(19) United States
(12) Patent Application Publication
(10) Pub. No.: US 2026/0324010 A1
(43) Pub. Date: Oct. 15, 2026

(54) TRENCH JFET AND METHOD OF MANUFACTURE

(71) Applicant: Microchip Technology Incorporated, Chandler, AZ (US)

(72) Inventor: Shesh Mani Pandey, Gilbert, AZ (US)

(73) Assignee: Microchip Technology Incorporated, Chandler, AZ (US)

(21) Appl. No.: 19/330,422

(22) Filed: Sep. 16, 2025

Related U.S. Application Data
(60) Provisional application No. 63/788,374, filed on Apr. 14, 2025.

(51) Int. Cl. H10D 30/83; H10D 30/01; H10D 62/17

(52) U.S. Cl. CPC H10D 30/831; H10D 30/0515; H10D 62/343

(57) ABSTRACT

A junction field effect transistor (JFET) includes a volume of semiconductor material, a source, and first and second gate contacts. The volume of semiconductor material includes a top, an opposite bottom spaced vertically from the top, a first side, a laterally opposite second side spaced from the first side, a first doped region, a second doped region, a drift region, and first and second trenches respectively along the first and second sides. The source is positioned along the top. The first and second gate contacts are respectively positioned in the first and second trenches. The drift region extends between the first and second doped regions. The first and second doped regions respectively define first and second junctions with the drift region including first and second topmost portions. The first and second gate contacts are vertically nearer to the top than the topmost portions of the first and second junctions.

### CROSS-REFERENCE TO RELATED APPLICATIONS

The current patent application claims the benefit under 35 U.S.C. § 119(e) of the priority date of U.S. Provisional Application Ser. No. 63/788,374; titled “TRENCH JFET AND METHOD OF MANUFACTURE”; and filed Apr. 14, 2025. The Provisional Application is hereby incorporated by reference, in its entirety, into the current patent application.

### TECHNICAL FIELD

The present disclosure relates to junction field effect transistors.

### BACKGROUND

A junction field-effect transistor (JFET) is an active, voltage-controlled semiconductor device, in which varying an electrical voltage between a gate and a source controls an electrical current flowing through a semiconductor channel between a drain and the source. Applications for JFETs include amplifiers, switches, resistors, regulators, oscillators, and choppers. It is generally desirable to improve the performance and reduce the cost of JFETs, but it can be difficult to do so.

This background discussion is intended to provide related information, and is not necessarily prior art.

### SUMMARY OF THE INVENTION

In various examples of the present disclosure, a junction field effect transistor (JFET) includes a volume of semiconductor material, a source, first and second gate contacts, a first doped region of the volume of semiconductor material having a first polarity, a second doped region of the volume of semiconductor material having the first polarity, and a drift region of the volume of semiconductor material having a second polarity opposite the first polarity. The volume of semiconductor material includes a top, an opposite bottom spaced vertically from the top, a first side, and a laterally opposite second side spaced from the first side. The volume of semiconductor material forms first and second trenches respectively along the first and second sides. The source is positioned along the top. The first and second gate contacts are respectively positioned in the first and second trenches. The first and second gate contacts are nearer to the bottom than the source is. The first doped region is adjacent the first gate contact. The second doped region is adjacent the second gate contact. The drift region extends between the first and second doped regions. The first and second doped regions respectively define first and second junctions with the drift region. The first and second junctions respectively include first and second topmost portions nearest the top. The first and second gate contacts respectively are vertically nearer to the top than the first and second topmost portions of the first and second junctions are.

In various examples of the present disclosure, a method of making a JFET includes: growing a volume of semiconductor material on a drain substrate; depositing laterally spaced first and second doped regions having a first polarity within the volume of semiconductor material; etching a first trench in the volume of semiconductor material; etching a second trench in the volume of semiconductor material; and placing respective first and second gate contacts within the first and second trenches. The volume of semiconductor material includes a top, an opposite bottom spaced vertically from the top, a first side, and a laterally opposite second side spaced from the first side. The volume of semiconductor material additionally includes a drift region having a second polarity opposite the first polarity. The drift region extends between the first and second doped regions. The first and second doped regions respectively define first and second junctions with the drift region. The first and second junctions respectively include first and second topmost portions nearest the top. The first trench is located adjacent the top and the first side and extends between the top and the first doped region. The first doped region is located adjacent the first trench. The second trench is located adjacent the top and the second side and extends between the top and the second doped region. The second doped region is located adjacent the second trench. The first and second gate contacts respectively are vertically nearer to the top than the first and second topmost portions of the first and second junctions are.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1 is a cross-sectional elevation view of an example trench JFET;

FIG. 2 is a method for manufacturing a trench JFET in accordance with the examples of the present disclosure;

FIG. 3A is a cross-sectional elevation view of an example JFET following epitaxial growth of a volume of semiconductor material in accordance with the examples of the present disclosure;

FIG. 3B is a cross-sectional elevation view of an example JFET following a first deposition of doped material into a volume of semiconductor material in accordance with the examples of the present disclosure;

FIG. 3C is a cross-sectional elevation view of an example JFET following a second deposition of doped material into a volume of semiconductor material in accordance with the examples of the present disclosure;

FIG. 3D is a cross-sectional elevation view of an example JFET following a third deposition of doped material into a volume of semiconductor material in accordance with the examples of the present disclosure;

FIG. 3E is a cross-sectional elevation view of an example JFET following an etching operation in accordance with the examples of the present disclosure; and

FIG. 3F is a cross-sectional elevation view of an example JFET following contact placement in accordance with the examples of the present disclosure.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower, vertical, horizontal (or lateral)) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Examples provide a trench junction field effect transistor (JFET). The example JFET may be suitable for high-voltage applications, and may operate at a voltage greater than one thousand (1,000) Volts (V). More specifically, the example JFET may be rated for a voltage of around twelve hundred (1,200) V. It would be appreciated by one of ordinary skill in the art that the example JFET may be suitable for lower voltage applications without departing from the scope of the present disclosure.

The example JFET may include a volume of semiconductor material forming trenches on either side of the semiconductor material. Laterally spaced apart first and second gate material regions are deposited within the volume of semiconductor material adjacent the trenches. A source is deposited along a top end of the semiconductor material. The semiconductor material includes a drift region located adjacent, above, and below the first and second gate material regions. Each gate material region respectively defines first and second junctions with the drift region. The first and second junctions respectively include first and second topmost portions nearest the top end of the volume of semiconductor material. First and second gate contacts, respectively located within the trenches, are respectively vertically nearer to the top end than the first and second topmost portions of the first and second junctions are. Accordingly, the gate material regions are vertically offset from the source such that a neck region located between the gate material regions is also vertically offset from the source.

In various examples, the example JFET may have reduced drain-induced barrier lowering (DIBL), which may improve the performance of the JFET by avoiding premature breakdown and reduced stability caused by excessive DIBL. Further, the vertical separation of gates and the source may prevent excessive amounts of the gate material from being removed while etching the trenches, thereby improving manufacturing consistency in addition to device stability and performance.

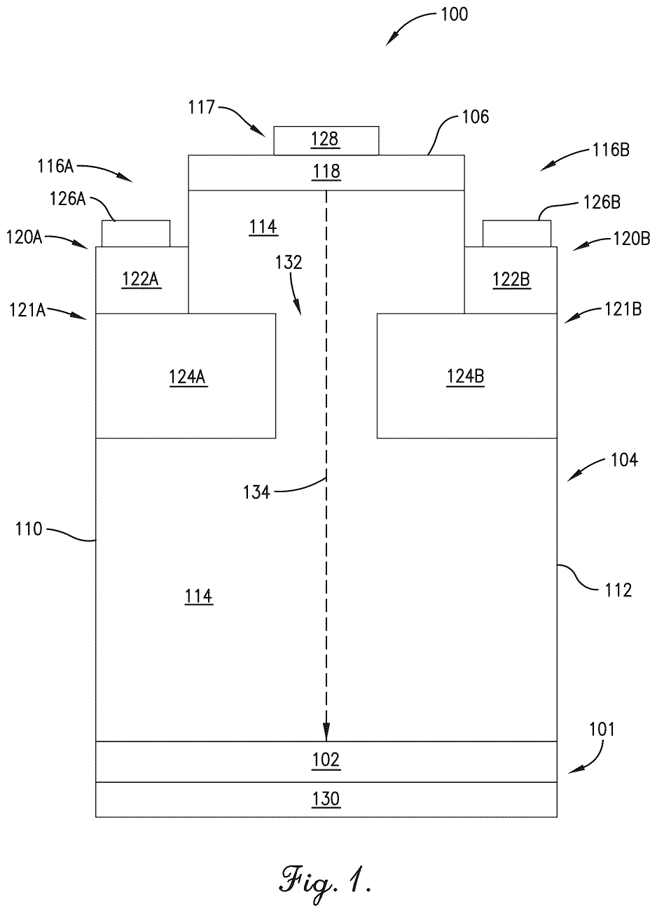

Referring to FIG. 1, an example of a JFET 100 is shown. The JFET 100 includes a drain electrode 101, a volume of semiconductor material 104, a source electrode 117, and laterally spaced apart first and second gates 120A, 120B. The drain electrode 101 includes a drain 102 and a drain contact 130. The drain 102 may comprise an N+ doped drain substrate. The volume of semiconductor material 104 may be epitaxially grown or otherwise formed on the drain substrate 102.

The volume of semiconductor material 104 includes a top end 106, an opposite bottom end 108 vertically spaced from the top 106, a first side 110, and a laterally opposite second side 112 spaced from the first side 110. The volume of semiconductor material 104 defines first and second trenches 116A, 116B respectively formed along the first and second sides 110, 112. The volume of semiconductor material 104 additionally includes a drift region 114 and a neck region 132. The drift region 114 includes a first drift region portion located above (e.g., along a vertical dimension) the neck region 132 and a second drift region portion located below (along the vertical dimension) the neck region 132. The drain 101 is located adjacent the bottom 108. The volume of semiconductor material 104 may include an N-type epitaxial semiconductor material.

The source electrode 117 includes a source 118 and a source contact 128. The source 118 may include doped source material deposited (e.g., via ion implantation) into or otherwise formed adjacent the top 106 and may extend laterally along a length of the top 108. The source contact 128 is placed on the top 108 adjacent the source 118.

In various examples, the neck region 132 may include a channel portion of the volume of semiconductor material 104, through which a channel 134 may be formed. The neck region 132 may be vertically offset from the source 118, with the first drift region portion extending between the source 118 and the neck region 132.

The first gate 120A includes a first doped region 121A of the volume of semiconductor material 104 and a first gate contact 126A. The first gate 120A is located adjacent the first side 110. The first doped region 121A is located adjacent the first trench 116A. The first gate contact 126A is located within the first trench 116A. The first doped region 121A has a first charge carrier polarity and may comprise a P+ doped material.

The second gate 120B includes a second doped region 121B of the volume of semiconductor material 104 and a second gate contact 126B. The second gate 120B is located adjacent the second side 112. The second doped region 121B is located adjacent the second trench 116B. The second gate contact 126B is located within the second trench 116B. The second doped region 121B has the first charge carrier polarity and may comprise a P+ doped material. The drift region 114 and the neck region 134 may comprise an N doped material having a second carrier polarity opposite the first charge carrier polarity.

The first and second gate contacts 126A, 126B are vertically offset from the source 118, such that the first and second gate contacts 126A, 126B are closer to the bottom 108 than the source 118 is to the bottom 108.

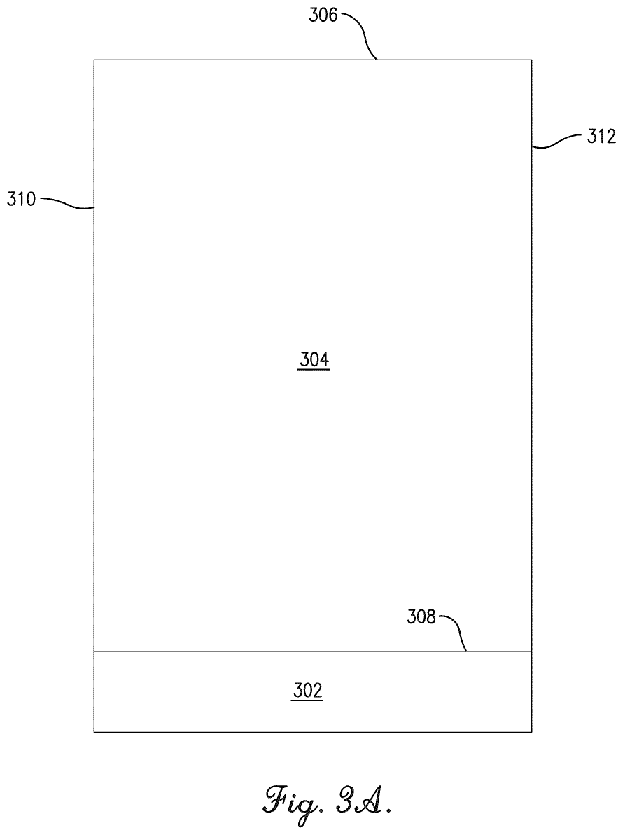

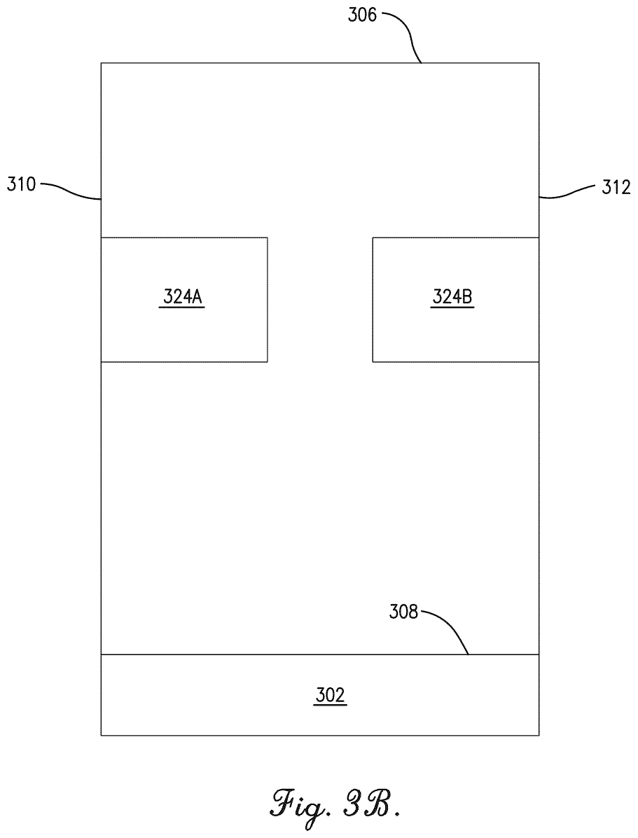

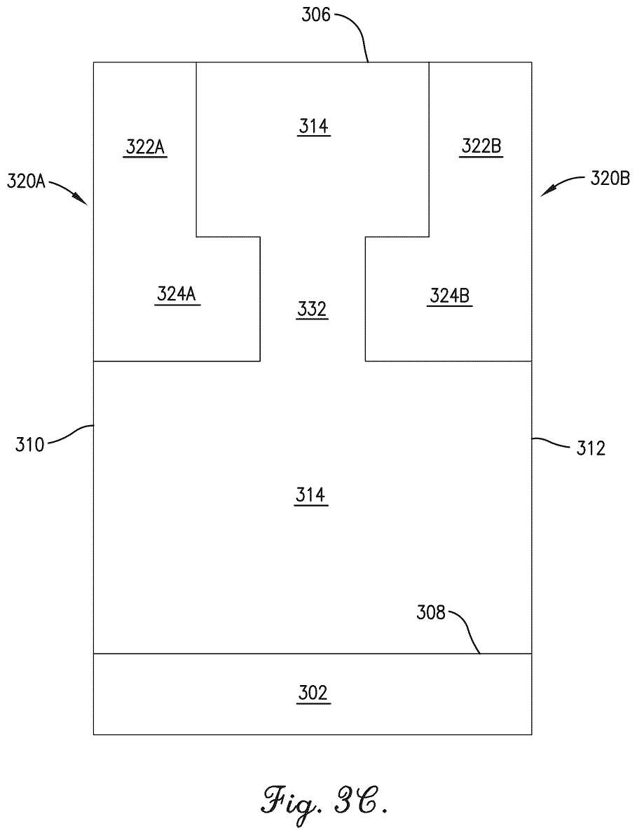

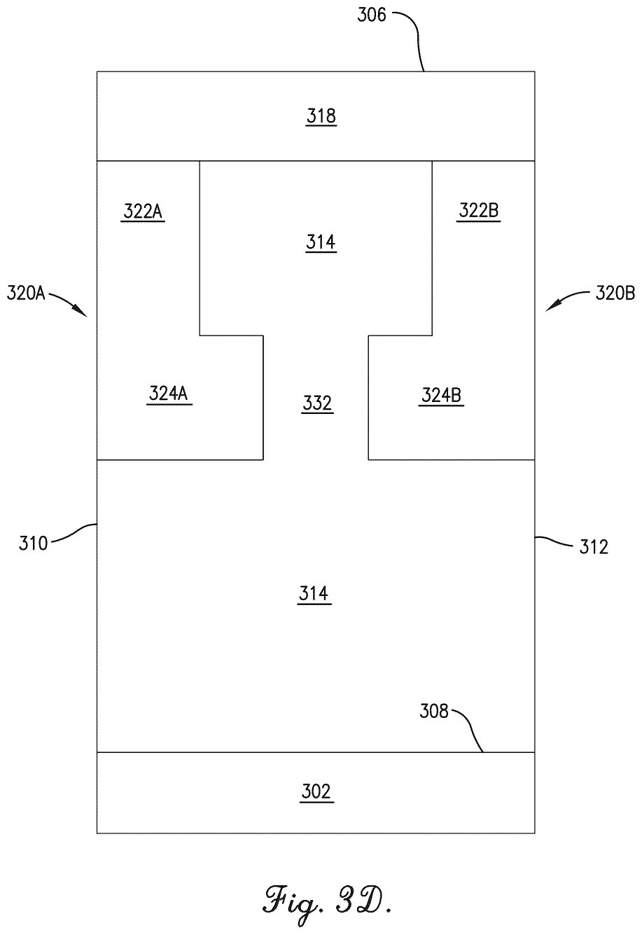

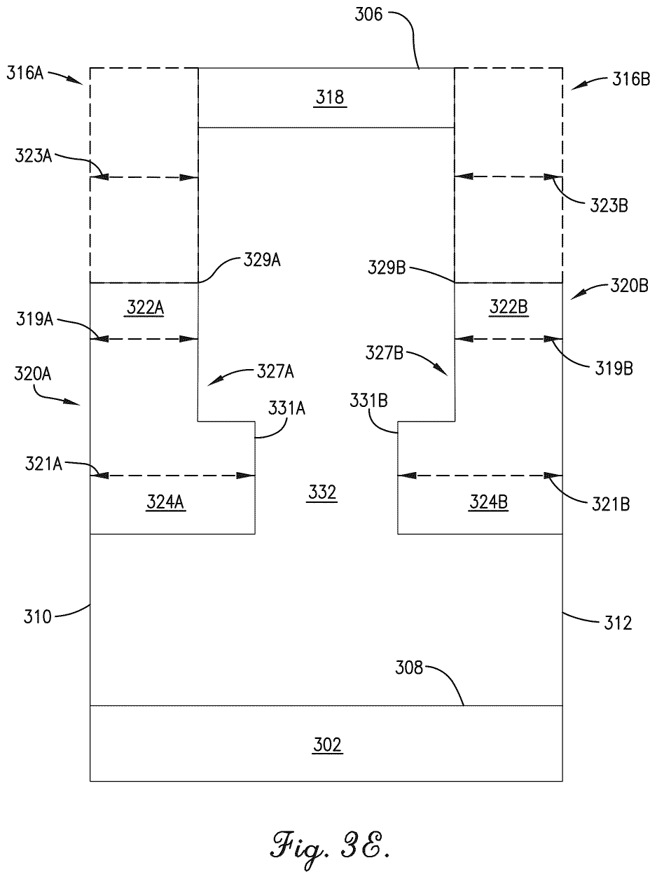

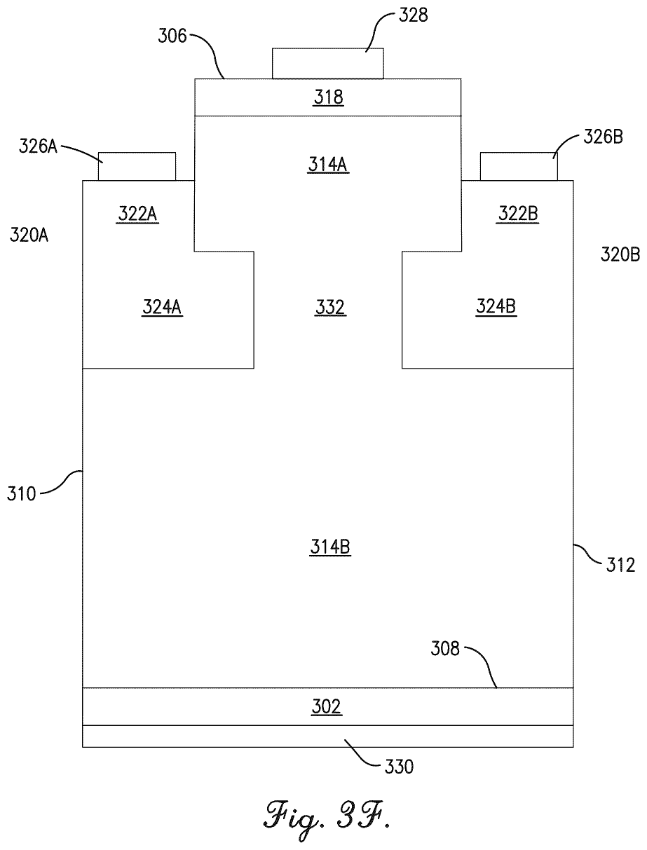

The first doped region 121A includes a first trench adjacent gate region 122A and a first buried gate region 124A. The first trench adjacent region 122A may extend from the first side 110 along a width of the trench 116A (as best shown in FIG. 3E) along a lateral dimension. The first buried gate region 124A may extend laterally from the first side 110 beyond the width of the first trench 116A.

The second doped region 121B includes a second trench adjacent gate region 122B and a first buried gate region 124B. The second trench adjacent region 122B may extend from the second side 112 along a width of the trench 116B (as best shown in FIG. 3E) in the lateral dimension. The second buried gate region 124B may extend laterally from the second side 112 beyond the width of the second trench 116B.

Edges of the first and second doped regions 121A, 121B define first and second junctions (e.g., first and second junctions 327A, 327B shown in FIG. 3E) between the gates 120A, 120B and both the drift region 114 and the neck region 132. It would be appreciated by one of ordinary skill in the art that although the edges are shown as straight lines, the edges of the doped regions 121A, 121B may not follow perfectly straight lines in practice.

The first and second junctions may include first and second topmost portions (e.g., first and second topmost portions 329A, 329B shown in FIG. 3E) nearest the top 106 along the vertical dimension. The first and second gate contacts 126A, 126B may be vertically nearer to the top 106 than the first and second topmost portions. The first and second gate contacts 126A, 126B are closer to the top 106 than any part of the first and second doped regions 121A, 121B.

The first and second junctions include innermost portions defined by the first and second buried gate regions 124A, 124B (e.g., innermost portions 331A, 331B shown in FIG. 3E). The neck region 132 extends between the innermost portions. Accordingly, respective widths of the buried gate portions 124A, 124B define a width of the neck region 132 along the lateral dimension. Respective heights of the buried gate regions 124A, 124B may define a height of the neck region 132 along the vertical dimension.

In various examples, the first doped region 121A and the second doped region 121B may be symmetrical. Accordingly, the first trench adjacent gate region 122A, the second trench adjacent gate region 122B, the first trench 116A, and the second trench 116B may have equal widths along the lateral dimension extending between the first and second sides 110, 112. The first buried gate region 124A and the second buried gate region 124B may have equal widths along the lateral dimension.

It would be appreciated by one of ordinary skill in the art that, because the first and second gates 120A, 120B, along with the neck region 132, are vertically offset from the source 118, manufacturing tolerances associated with etching of the trenches 116A, 116B may allow for slight asymmetry between the first and second doped regions 121A, 121B without significant performance degradation. Moreover, no portion of either of the buried gate sections 124A, 124B is etched, which preserves the dimensions of the neck region 134 during manufacture, thereby enabling consistent transistor production and performance.

In an alternative example, the first and second doped regions 121A, 121B may be asymmetrical without departing from the scope of the present disclosure. In various examples, each gate 120A, 120B may be driven by an equal voltage or respectively different voltages within the scope of the present disclosure.

During operation, one or more voltages applied to the first and second gate contacts 126A, 126B may energize the doped material regions 121A, 121B, forming the channel 134 in which charge carriers may flow between the source 118 and the drain 102. The charge carriers may move and electrical current may flow through the channel 134. It will be understood by one of ordinary skill in the art that the dashed line representing the channel 134 is merely representative and charge carriers moving through the channel 134 do not necessarily follow a straight line.

It will be appreciated that the example JFET is an N-channel JFET. However, certain aspects of the example JFET might be applicable to P-channel JFETs.

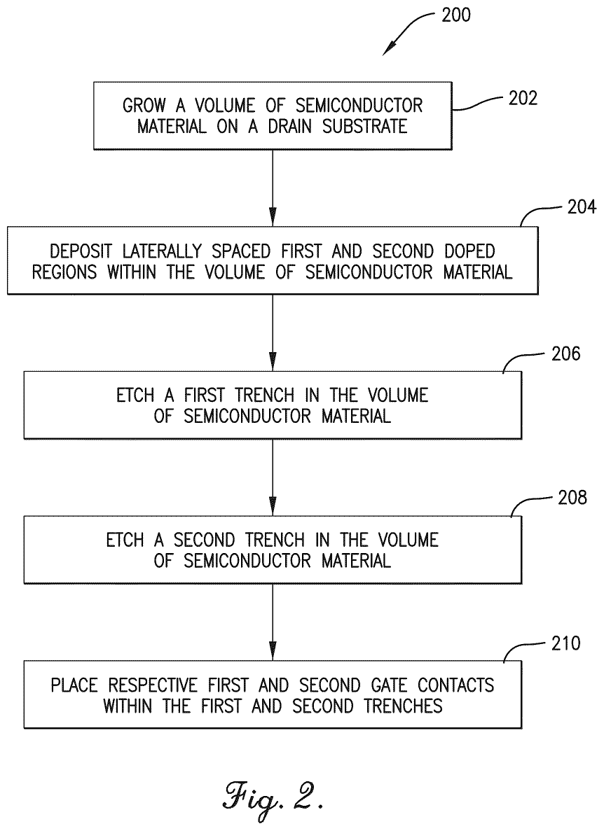

Referring to FIG. 2, an example of a method 200 of manufacturing a JFET, such as the JFET 100 described above, may include the operations set forth below. Referring additionally to FIGS. 3A-F, example results of various operations are shown.

At operation 202, a volume of semiconductor material 304 is epitaxially grown or otherwise formed on a drain substrate 302. The volume of semiconductor material 304 includes a top 306 an opposite bottom 308 vertically spaced from the top 306, a first side 310, and a laterally opposite second side 312 spaced from the first side 310, as shown in FIG. 3A. The drain substrate 302 may include an N+ substrate material. The volume of semiconductor material 304 may include an N type epitaxial semiconductor material.

At operation 204, laterally spaced doped regions 320A, 320B are deposited (e.g., via ion implantation) or otherwise provided within the volume of semiconductor material 304, as shown in FIGS. 3B and 3C. The laterally spaced doped regions 320A, 320B have a first polarity. The laterally spaced doped regions 320A, 320B may comprise a P+ doped material.

The first doped region 320A includes a first trench adjacent gate region 322A and a first buried gate region 324A. The second doped region 320B includes a second trench adjacent gate region 322B and a second buried gate region 324B.

As shown in FIG. 3B, the first buried gate region 324A may be deposited adjacent the first side 310 and vertically spaced from the top end 306. The second buried gate region 324B may be deposited adjacent the second side 312 and vertically spaced from the top end 306.

As shown in FIG. 3C, the first trench adjacent gate region 322A may be deposited adjacent the top end 306 and the first side 310. The first trench adjacent gate region 322A may extend vertically from the top end 306 toward the first buried gate region 324A. The first trench adjacent gate region 322A and the first buried gate region 324A may contact each other to collectively form the first doped region 320A. The second trench adjacent gate region 322B may be deposited adjacent the top end 306 and the second side 312. The second trench adjacent gate region 322B may extend vertically from the top end 306 toward the second buried gate region 324B. The second trench adjacent gate region 322B and the second buried gate region 324B may contact each other to collectively form the second doped region 320B.

The volume of semiconductor material 304 includes a drift region 314 having a second polarity opposite the first polarity. The drift region 314 extends between the first and second doped regions 320A, 320B.

As shown in FIG. 3D, a neck region 332 of the volume of semiconductor material 304 may extend between the first and second buried gate regions 324A, 324B.

In various examples, a source 318 may be deposited adjacent and along the top end 306 of the volume of semiconductor material 304. The source 318 may extend laterally between the first side 310 and the second side 312. The source may include an N+ doped material.

In various examples, the first and second buried gate regions 324A, 324B may be deposited prior to deposition of the first and second trench adjacent gate regions 322A, 322B, as shown in FIGS. 3B and 3C. The source 318 may be deposited following deposition of the first and second doped gate regions 320A, 320B, as shown in FIGS. 3C and 3D. The source 318 may be deposited adjacent the top 306. As shown in FIG. 3D, the source 318 may extend from the first side 310 to the second side 312, with lateral extremities replacing portions of the first and second trench adjacent gate regions 322A, 322B. It would be appreciated by one of ordinary skill in the art that any of the first buried gate region 324A, second buried gate region 324B, first trench adjacent gate region 322A, second trench adjacent gate region 322B, and the source 318 may be deposited in any order without departing from the scope of the present disclosure.

At operation 206, a first trench 316A is etched in the volume of semiconductor material 304 adjacent the top 306 and the first side 310. The first trench 316A extends between the top 306 and the first doped region 320A. The first doped region 320A is located adjacent the first trench 316A. Etching the first trench 316A may include etching a portion of the first trench adjacent gate region 322A and/or a portion of the source 318.

As shown in FIG. 3E, the first trench adjacent gate region 322A has a first width 319A extending in a lateral dimension between the first side 310 and the second side 312. The first buried gate region 324A has a second width 321A extending along the lateral dimension. The first trench 316A has a first trench width 323A extending along the lateral dimension. The first width 319A and the first trench width 323A may be equal. The second width 321A may be greater than both the first width 319A and the first trench width 323A.

Edges of the first doped material region 320A may define a first junction 327A between the first doped material region 320A and both the drift region 314 and the neck region 332. The first junction 327A includes a topmost portion 329A that is closest to the top end 306 and the source 318 than any other portion of the first junction 327A. The first junction 327A includes a first innermost portion 331A closest to the second side 112 than any other portion of the first junction 327A. The first innermost portion contacts the neck region 332.

At operation 208, a second trench 316B is etched in the volume of semiconductor material 304 adjacent the top 306 and the second side 312. The second trench 316B extends between the top 306 and the second doped region 320B. The second doped region 320B is located adjacent the second trench 316B. Etching the second trench 316B may include etching a portion of the second trench adjacent gate region 322B and/or a portion of the source 318.

As shown in FIG. 3E, the second trench adjacent gate region 322B has a third width 319B extending along the lateral dimension. The second buried gate region 324B has a fourth width 321B extending along the lateral dimension. The second trench 316B has a second trench width 323B extending along the lateral dimension. The third width 319B and the second trench width 323B may be equal. The fourth width 321B may be greater than both the third width 319B and the second trench width 323B.

The first and second trench widths 323A, 323B may be equal. The first and third widths 319A, 319B may be equal. The first and second trench widths 323A, 323B and the first and third widths 319A, 319B may be equal. The second and fourth widths 321A, 321B may be equal. The second and fourth widths 321A, 321B may be greater than any of the first and second trench widths 323A, 323B and the first and third widths 319A, 319B.

Edges of the second doped material region 320B may define a second junction 327B between the second doped material region 320B and both the drift region 314 and the neck region 332. The second junction 327B includes a topmost portion 329B that is closer to the top end 306 and the source 318 than any other portion of the second junction 327B. The second junction 327B includes a second innermost portion 331B closer to the first side 110 than any other portion of the second junction 327B. The second innermost portion 331B contacts the neck region 332.

A width of the neck region 332 in the lateral dimension may be defined by the second and fourth widths 321A, 321B. A height of the neck region 332 in a vertical dimension (e.g., extending between the top 306 and the bottom 308) may be defined by a height of the first and second buried gate regions 324A, 324B in the vertical dimension.

As shown in FIG. 3E, the first and second doped regions 320A, 320B may be vertically spaced from the source 318 following etching of the first and second trenches 316A, 316B.

At operation 210, respective first and second gate contacts 326A, 326B are placed within the respective first and second trenches 316A, 316B. As shown in FIG. 3F, respective vertical distances between the first and second gate contacts 326A, 326B and the bottom 308 may be less than a vertical distance between the source 318 and the bottom 308. Accordingly, the first and second gate contacts 326A, 326B may be vertically nearer to the bottom than the source 318 is. The first and second gate contacts 326A, 326B may each be located vertically nearer to the source 318 than either of the topmost portions 329A, 329B is. Accordingly, the first and second doped regions 320A, 320B do not extend vertically above either of the first and second gate contacts 326A, 326B.

A source contact 328 may be placed vertically above the source 318. A drain contact 330 may be placed vertically below the drain substrate 302.

As shown in FIG. 3F, the drift region 314 may include a first drift region portion 314A and a second drift region portion 314B. The first drift region portion 314A may extend vertically and be interposed between the source 318 and the neck region 332 and horizontally between the first trench 316A and the second trench 316B. The first drift region portion 314A extends vertically between a portion of the first buried gate region 324A and the source 318. The first drift region portion 314A extends vertically between a portion of the second buried gate region 324B and the source 318. A portion of the first drift region portion 314A extends vertically between the source 318 and each of the first and second topmost portions 329A, 329B. The first drift region portion 314A extends laterally between first and second trench adjacent gate regions 322A, 322B. The second drift region portion 314B may extend vertically between the neck region 332 and the drain substrate 302 and horizontally between the first side 310 and the second side 312. Portion(s) of the first drift region portion 314A may extend vertically closer to the bottom 308 than either of the first and second trenches 316A, 316B. Accordingly, the first drift region portion 314A may extend above and between the first and second doped regions 320A, 320B such that the first and second doped regions 320A, 320B are vertically offset from and do not contact the source 318.

### Feature Combinations

In accordance with various examples of the present disclosure, a JFET may include a volume of semiconductor material, a source, first and second gate contacts, a first doped region of the volume of semiconductor material having a first polarity, a second doped region of the volume of semiconductor material having the first polarity, and a drift region of the volume of semiconductor material having a second polarity opposite the first polarity. The volume of semiconductor material may include a top, an opposite bottom spaced vertically from the top, a first side, and a laterally opposite second side spaced from the first side. The volume of semiconductor material may form first and second trenches respectively along the first and second sides. The source may be positioned along the top. The first and second gate contacts may be respectively positioned in the first and second trenches. The first and second gate contacts are nearer to the bottom than the source is. The first doped region is adjacent the first gate contact. The second doped region is adjacent the second gate contact. The drift region extends between the first and second doped regions. The first and second doped regions respectively define first and second junctions with the drift region. The first and second junctions respectively include first and second topmost portions nearest the top. The first and second gate contacts respectively are vertically nearer to the top than the first and second topmost portions of the first and second junctions are.

In combination with any of the previous examples, an example JFET may include a drain located at a bottom.

In combination with any of the previous examples, a volume of semiconductor material may an N-type epitaxial material. A source may include an N+ material. A drain may include an N+ material. First and second doped regions may include a P+ material.

In combination with any of the previous examples, an example JFET may include a source contact located adjacent a source and a drain contact located adjacent a drain.

In combination with any of the previous examples, a drift region may include a first drift region portion and a second drift region portion. The first drift region portion may extend between first and second doped regions and a source. The second drift region portion may extend between the first and second doped regions and the drain.

In combination with any of the previous examples, a first drift region portion may extend toward a bottom beyond first and second trenches.

In combination with any of the previous examples, first and second doped regions may be symmetrical.

In combination with any of the previous examples, first and second doped regions may be vertically spaced apart from a source.

In combination with any of the previous examples, a first doped region may include a first trench adjacent gate region and a first buried gate region. A second doped region may include a second trench adjacent gate region and a second buried gate region. The first trench adjacent gate region may have a first width. The first buried gate region may have a second width. The second trench adjacent gate region may have a third width. The second buried gate region may have a fourth width. Each of the second and forth widths may be greater than each of the first and third widths.

In combination with any of the previous examples, first and third widths may be equal. Second and fourth widths may be equal.

In combination with any of the previous examples, a first trench may have a first trench width. A second trench may have a second trench width. The first trench width and the second trench width may be equal. The first trench width and the first width may be equal. The second trench width and the third width may be equal.

In combination with any of the previous examples, first and second junctions may respectively include first and second innermost portions respectively farthest from first and second sides. An example JFET may include a channel provided by a neck region of a volume of semiconductor material. The neck region may extend between the innermost portions and may be vertically offset from a source.

In various examples of the present disclosure, a method of making a JFET may include: growing a volume of semiconductor material on a drain substrate; depositing laterally spaced first and second doped regions having a first polarity within the volume of semiconductor material; etching a first trench in the volume of semiconductor material; etching a second trench in the volume of semiconductor material; and placing respective first and second gate contacts within the first and second trenches. The volume of semiconductor material may include a top, an opposite bottom spaced vertically from the top, a first side, and a laterally opposite second side spaced from the first side. The volume of semiconductor material may additionally include a drift region having a second polarity opposite the first polarity. The drift region may extend between the first and second doped regions. The first and second doped regions may respectively define first and second junctions with the drift region. The first and second junctions may respectively include first and second topmost portions nearest the top. The first trench may be located adjacent the top and the first side and may extend between the top and the first doped region. The first doped region may be located adjacent the first trench. The second trench may be located adjacent the top and the second side and may extend between the top and the second doped region. The second doped region may be located adjacent the second trench. The first and second gate contacts respectively may be vertically nearer to the top than the first and second topmost portions of the first and second junctions are.

In combination with any of the previous examples, a method of making a JFET may include: depositing a source along a top; placing a source contact adjacent a source; and placing a drain contact adjacent a substate.

In combination with any of the previous examples, depositing first and second doped portions may include: depositing a first trench adjacent gate region adjacent a first side; depositing a first buried gate region adjacent the first side; depositing a second trench adjacent gate region adjacent the second side; and depositing a second buried gate region adjacent the second side. The first buried gate region may extend toward the second side beyond the first trench adjacent gate region. The second buried gate region may extend toward the first side beyond the second trench adjacent gate region.

In combination with any of the previous examples, etching a first trench may include etching a portion of a first trench adjacent gate region. Etching a second trench may include etching a portion of a second trench adjacent gate region. The first and second trench adjacent gate regions may be vertically spaced apart from a top.

In combination with any of the previous examples, a first gate contact may be placed adjacent a first trench adjacent gate region. A second gate contact may be placed adjacent a second trench adjacent gate region.

In combination with any of the previous examples, a first trench and a first trench adjacent gate region may have equal widths. A second trench and a second trench adjacent gate region may have equal widths. First and second buried gate regions may have equal widths.

### General Considerations

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

For example, although described herein with regard or in relation to one or more particular kinds of electronic devices (e.g., junction field-effect transistor), the technology may be more broadly applicable to one or more other kinds of electronic devices as well. Further, one with ordinary skill in the art will recognize that the technology described herein may, when applicable, be implemented in enhancement mode or depletion mode. Additionally, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum dioxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations (measured in parts per cubic centimeter) for contact implants may be approximately between 10\hat{ }18 and 10\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region may be approximately between 10\hat{ }16 and 10\hat{ }17. Relatedly, a structure or region may contain two or more different doping doses. For example, one with ordinary skill in the art will recognize that some P-wells may contain a lower dose P-well portion and a higher dose unclamped inductive switching portion.

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

What is claimed is:

1. A junction field-effect transistor (JFET) comprising:
a volume of semiconductor material including a top, an opposite bottom spaced vertically from the top, a first side, and a laterally opposite second side spaced from the first side, the volume of semiconductor material forming first and second trenches respectively along the first and second sides;
a source positioned along the top;
first and second gate contacts respectively positioned in the first and second trenches, the first and second gate contacts being nearer the bottom than the source;
a first doped region of the volume of semiconductor material adjacent the first gate contact having a first polarity;
a second doped region of the volume of semiconductor material adjacent the second gate contact having the first polarity; and
a drift region of the volume of semiconductor material having a second polarity opposite the first polarity, the drift region extending between the first and second doped regions,
the first and second doped regions respectively defining first and second junctions with the drift region, the first and second junctions respectively including first and second topmost portions nearest the top,
the first and second gate contacts respectively being vertically nearer to the top than the first and second topmost portions of the first and second junctions.

2. The JFET of claim 1, comprising:
a drain located at the bottom.

3. The JFET of claim 2,
the volume of semiconductor material including an N-type epitaxial material,
the source including an N+ material,
the drain including an N+ material,
the first and second doped regions including a P+ material.

4. The JFET of claim 2, comprising:
a source contact located adjacent the source; and
a drain contact located adjacent the drain.

5. The JFET of claim 2, the drift region including—
a first drift region portion extending between the first and second doped regions and the source; and
a second drift region portion extending between the first and second doped regions and the drain.

6. The JFET of claim 5, the first drift region portion extending toward the bottom beyond the first and second trenches.

7. The JFET of claim 1, the first and second doped regions being symmetrical.

8. The JFET of claim 1, the first and second doped regions being vertically spaced apart from the source.

9. The JFET of claim 1,
the first doped region including a first trench adjacent gate region and a first buried gate region,
the second doped region including a second trench adjacent gate region and a second buried gate region,
the first trench adjacent gate region having a first width,
the first buried gate region having a second width,
the second trench adjacent gate region having a third width,
the second buried gate region having a fourth width,
each of the second and forth widths being greater than each of the first and third widths.

10. The JFET of claim 9, the first and third widths being equal, the second and fourth widths being equal.

11. The JFET of claim 9, the first trench having a first trench width, the second trench having a second trench width, the first trench width and the second trench width being equal, the first trench width and the first width being equal, the second trench width and the third width being equal.

12. The JFET of claim 1, the first and second junctions respectively including first and second innermost portions respectively farthest from the first and second sides, comprising:
a channel provided by a neck region of the volume of semiconductor material, the neck region extending between the innermost portions and being vertically offset from the source.

13. A method of making a junction field-effect transistor (JFET) comprising:
growing a volume of semiconductor material on a drain substrate, the volume of semiconductor material including a top, an opposite bottom spaced vertically from the top, a first side, and a laterally opposite second side spaced from the first side;
depositing laterally spaced first and second doped regions having a first polarity within the volume of semiconductor material, the volume of semiconductor material including a drift region having a second polarity opposite the first polarity, the drift region extending between the first and second doped regions;
etching a first trench in the volume of semiconductor material adjacent the top and the first side, the first trench extending between the top and the first doped region, the first doped region being located adjacent the first trench;
etching a second trench in the volume of semiconductor material adjacent the top and the second side, the second trench extending between the top and the second doped region, the second doped region being located adjacent the second trench; and
placing respective first and second gate contacts within the first and second trenches,
the first and second doped regions respectively defining first and second junctions with the drift region, the first and second junctions respectively including first and second topmost portions nearest the top,
the first and second gate contacts respectively being vertically nearer to the top than the first and second topmost portions of the first and second junctions.

14. The method of claim 13, the first and second doped regions being symmetrical.

15. The method of claim 13, comprising:
depositing a source along the top;
placing a source contact adjacent the source; and
placing a drain contact adjacent the substate.

16. The method of claim 15,
the volume of semiconductor material including an N-type epitaxial material,
the source including an N+ material,
the drain substrate including an N+ material,
the first and second doped regions including a P+ material.

17. The method of claim 13, wherein depositing the first and second doped portions includes:
depositing a first trench adjacent gate region adjacent the first side;
depositing a first buried gate region adjacent the first side, the first buried gate region extending toward the second side beyond the first trench adjacent gate region;
depositing a second trench adjacent gate region adjacent the second side; and
depositing a second buried gate region adjacent the second side, the second buried gate region extending toward the first side beyond the second trench adjacent gate region.

18. The method of claim 17, wherein etching the first trench includes etching a portion of the first trench adjacent gate region and etching the second trench includes etching a portion of the second trench adjacent gate region, such that the first and second trench adjacent gate regions are vertically spaced apart from the top.

19. The method of claim 18, wherein the first gate contact is placed adjacent the first trench adjacent gate region and the second gate contact is placed adjacent the second trench adjacent gate region.

20. The method of claim 18, the first trench and the first trench adjacent gate region having equal widths, the second trench and the second trench adjacent gate region having equal widths, the first and second buried gate regions having equal widths.
